(19) United States
(12) Patent Application Publication
(10) Pub. No.: US 2026/0303054 A1
(43) Pub. Date: Oct. 1, 2026

(54) BAW RESONATOR WITH ZERO ELECTROMECHANICAL COUPLING IN BORDER REGIONS AND FLAT, STEEP SKIRTS AND SQUARED SHOULDERS

(71) Applicant: Qorvo US, Inc., Greensboro, NC (US)

(72) Inventors: Alireza Tajic, Winter Springs, FL (US); Thomas Berer, Apopka, FL (US); Istvan Veres, Longwood, FL (US)

(21) Appl. No.: 18/996,352

(22) PCT Filed: Aug. 21, 2023
(86) PCT No.: PCT/US2023/030691

§ 371 Date: Jan. 17, 2025

Related U.S. Application Data
(60) Provisional application No. 63/407,459, filed on Sep. 16, 2022.

(51) Int. Cl. H03H 9/02; H03H 9/13; H03H 9/17

(52) U.S. Cl. CPC H03H 9/02031; H03H 9/02157; H03H 9/131; H03H 9/133; H03H 9/176

(57) ABSTRACT

The present disclosure relates to a bulk acoustic wave, BAW, resonator, which includes a bottom electrode (56), a top electrode (60), and a piezoelectric layer (58) sandwiched between the bottom electrode and the top electrode. Herein, an active region of the BAW resonator is divided into a central region (82), a recessed border, BO, region (92) laterally contiguous to and surrounding the central region, and a mass loading BO (94) region laterally contiguous to and surrounding the recessed BO region. A height (H1) of the recessed BO region is less than a height of the central region (H3) and less than a height (H2) of the mass loading region. A first portion (76) of the piezoelectric layer, which is confined in the mass loading BO region, has a zero electromechanical coupling tensor, while a central portion (77) of the piezoelectric layer, which is confined in the central region, has a non-zero electromechanical coupling tensor.

### RELATED APPLICATIONS

This application claims the benefit of provisional patent application Ser. No. 63/407,459, filed Sep. 16, 2022, the disclosure of which is hereby incorporated herein by reference in its entirety.

### FIELD OF THE DISCLOSURE

The present disclosure relates to a Bulk Acoustic Wave (BAW) resonator with zero-coupling in border (BO) regions of the BAW resonator.

### BACKGROUND

Acoustic resonators and, particularly, bulk acoustic wave (BAW) resonators are used in many high-frequency, communication applications. In particular, BAW resonators are often employed in filter networks that operate at frequencies above 1.5 gigahertz (GHz) and require a flat passband, have exceptionally steep filter skirts and squared shoulders at the upper and lower ends of the passband, and provide excellent rejection outside of the passband.

BAW-based filters also have relatively low insertion loss, tend to decrease in size as the frequency of operation increases, and are relatively stable over wide temperature ranges. As such, BAW-based filters are the filter of choice for many 3rd Generation (3G) and 4th Generation (4G) wireless devices, and are destined to dominate filter applications for 5th Generation (5G) wireless devices. Most of these wireless devices support cellular, wireless fidelity (Wi-Fi), Bluetooth, and/or near field communications on the same wireless device, and as such, pose extremely challenging filtering demands. While these demands keep raising the complexity of the wireless devices, there is a constant need to improve the performance of BAW resonators and BAW-based filters as well as decrease the cost and size associated therewith.

### SUMMARY

The present disclosure relates to a bulk acoustic wave (BAW) resonator with zero-coupling within border (BO) regions of the BAW resonator. The disclosed BAW resonator includes a bottom electrode, a top electrode, and a piezoelectric layer sandwiched between the bottom electrode and the top electrode. Herein, the BAW resonator is divided into an active region and an outside region. The active region corresponds to a section of the BAW resonator where the top electrode and the bottom electrode overlap, while the outside region corresponds to sections of the BAW resonator surrounding the active region. The active region is divided into a central region, a recessed border (BO) region, and a mass loading BO region. The mass loading BO region is laterally contiguous to the outside region and about a periphery of the active region, the recessed BO region is laterally contiguous to and surrounded by the mass loading BO region, and the central region is laterally contiguous to and surrounded by the recessed BO region. A height of the recessed BO region is less than a height of the central region and a height of the mass loading BO region is greater than the height of the recessed BO region. A first portion of the piezoelectric layer, which is confined in the mass loading BO region, has a zero electromechanical coupling tensor, while a central portion of the piezoelectric layer, which is confined in the central region, has a non-zero electromechanical coupling tensor.

In one embodiment of the BAW resonator, a second portion of the piezoelectric layer, which is confined in the recessed BO region, has a zero electromechanical coupling tensor. A third portion of the piezoelectric layer, which is confined in the outside region, has a zero electromechanical coupling tensor.

In one embodiment of the BAW resonator, the piezoelectric layer is formed of one of a group consisting of Scandium aluminum nitride, Lead Zirconate Titanate, Lead titanate, Barium Titanate, and Hafnium Oxide.

In one embodiment of the BAW resonator, the height of the mass loading BO region is greater than the height of the central region.

In one embodiment of the BAW resonator, the height of the central region is greater than the height of the mass loading BO region.

In one embodiment of the BAW resonator, the BAW resonator is a Type-I resonator or a Type-II resonator.

In one embodiment of the BAW resonator, a second portion of the piezoelectric layer, which is confined in the recessed BO region, has a non-zero electromechanical coupling tensor. A third portion of the piezoelectric layer, which is confined in the outside region, has a zero electromechanical coupling tensor. The BAW resonator is a Type-II resonator.

In one embodiment of the BAW resonator, the top electrode includes a BO structure about a periphery of the top electrode. Herein, the BO structure has a recessed frame with a first height, a raised frame with a second height greater than the first height, and a transition section laterally between the recessed frame and the raised frame. A height of the transition section varies from the first height of the recessed frame to the second height of the raised frame to form a tapered wall. The raised frame is about the periphery of the top electrode, such that outer peripheral edges of the raised frame are peripheral edges of the top electrode. The recessed frame is connected to the raised frame via the transition section and surrounded by the raised frame. A central electrode portion of the top electrode, which is confined in the central region of the BAW resonator, has a third height that is greater than the first height of the recessed frame. The recessed BO region corresponds to sections of the BAW resonator that include, reside over, and reside below the recessed frame, and the mass loading BO region corresponds to sections of the BAW resonator that include, reside over, and reside below the raised frame and the transition section. A height variation among the central region, the recessed BO region, and the mass loading BO region is formed due to a height variation of the top electrode.

In one embodiment of the BAW resonator, the top electrode is composed of a first top electrode layer formed directly over the piezoelectric layer, a second top electrode layer formed over the first top electrode layer, and a third top electrode layer formed over the second top electrode layer. The recessed frame, the transition section, and the raised frame of the top electrode are formed due to thickness variations of one or more of the first top electrode layer, the second top electrode layer, and the third top electrode layer.

In one embodiment of the BAW resonator, the recessed frame, the transition section, and the raised frame of the top electrode are formed due to a thickness variation of the first top electrode layer.

In one embodiment of the BAW resonator, the first top electrode layer is formed of one of tungsten (W), molybdenum (Mo), platinum (Pt), the second electrode layer is formed of Titanium Tungsten (TiW) or Titanium (Ti), and the third top electrode layer is formed of aluminum copper (AlCu).

According to one embodiment, the BAW resonator further includes a passivation layer that covers the top electrode and portions of the piezoelectric layer exposed through the top electrode. Herein, the passivation layer has a uniform thickness.

In one embodiment of the BAW resonator, the top electrode includes a BO structure about the periphery of the top electrode. Herein, the BO structure includes a recessed frame with a first height, an inner raised frame with a second height, a first transition section laterally between the recessed frame and the inner raised frame, an outer raised frame with a third height, and a second transition section laterally between the inner raised frame and the outer raised frame. The second height is greater than the first height and less than the third height. A height of the first transition section varies from the first height of the recessed frame to the second height of the inner raised frame, while a height of the second transition section varies from the second height of the inner raised frame to the third height of the outer raised frame. The outer raised frame is about the periphery of the top electrode, such that outer peripheral edges of the outer raised frame are peripheral edges of the top electrode. The inner raised frame is connected to the outer raised frame via the second transition section and surrounded by the outer raised frame. The recessed frame is connected to the inner raised frame via the first transition section and surrounded by the inner raised frame. A central electrode portion of the top electrode, which is confined in the central region of the BAW resonator, has a fourth height that is greater than the first height of the recessed frame. The recessed BO region corresponds to sections of the BAW resonator that include, reside over, and reside below the recessed frame, and the mass loading BO region corresponds to sections of the BAW resonator that include, reside over, and reside below a combination of the first transition section, the inner raised frame, the second transition section, and the outer raised frame.

According to one embodiment, the BAW resonator further includes a dielectric BO ring about the periphery of the active region. Herein, the top electrode is composed of multiple top electrode layers that are formed directly over the piezoelectric layer and extend over the dielectric BO ring. A height variation among the central region, the recessed BO region, and the mass loading BO region is formed due to a combination of a thickness variation of the top electrode layers of the top electrode and a thickness of the dielectric BO ring.

According to one embodiment, the BAW resonator further includes a passivation layer that covers the top electrode and portions of the piezoelectric layer exposed through the top electrode, wherein the passivation layer is formed of Silicon Nitride (SIN), silicon dioxide (SiO2), or Silicon Oxynitride (SiON).

In one embodiment of the BAW resonator, the top electrode includes a BO structure with a raised frame and a transition section, and the passivation layer includes a recessed frame. The raised frame is about the periphery of the top electrode, such that outer peripheral edges of the raised frame are peripheral edges of the top electrode, and the transition section is laterally contiguous to and surrounded by the raised frame. The recessed frame of the passivation layer is laterally adjacent to and confined in the transition section of the top electrode. A thickness of the recessed frame is less than a thickness of the passivation layer within the central region. The recessed BO region corresponds to sections of the BAW resonator that include and reside below the recessed frame of the passivation layer, and the mass loading BO region corresponds to sections of the BAW resonator that include, reside over, and reside below the raised frame and the transition section.

In one embodiment of the BAW resonator, the top electrode is composed of multiple top electrode layers that are formed directly over the piezoelectric layer. A height variation among the central region, the recessed BO region, and the mass loading BO region is formed due to the recessed frame of the passivation layer and the BO structure of the top electrode.

In one embodiment of the BAW resonator, portions of the top electrode confined within the central region and the recessed BO region have a uniform thickness, and a height variation between the central region and the recessed BO region is due to a thickness variation of the passivation layer. A height variation between the recessed BO region and the mass loading BO region is due to a thickness variation of the top electrode layers.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a diagram illustrating a conventional bulk acoustic wave (BAW) resonator.

FIG. 2 is a diagram graphically illustrating the magnitude and phase of the electrical impedance as a function of the frequency for a relatively ideal BAW resonator.

FIGS. 3A-3C are diagrams graphically illustrating phase curves for various conventional BAW resonators.

FIG. 4 is a diagram illustrating a conventional BAW resonator with a top electrode including a border (BO) ring.

FIG. 5 is a diagram graphically illustrating the relationship of the BO ring width to a quality factor at an antiresonance frequency (Qₚ) and the relative strength of BO modes formed.

FIG. 6 is a diagram graphically illustrating phase curves for BAW resonators with and without BO rings.

FIG. 7 is a cross-sectional diagram illustrating an exemplary BAW resonator with zero-coupling in BO regions according to embodiments of the present disclosure.

FIG. 8 is a cross-sectional diagram illustrating details of a top electrode within the BAW resonator shown in FIG. 7.

FIGS. 9-11 are cross-sectional diagrams illustrating an alternative BAW resonator with zero-coupling in BO regions according to embodiments of the present disclosure.

FIGS. 12A-12B illustrate simulation results for various configurations of a Type-I BAW resonator.

FIGS. 13A-13B illustrate simulation results for various configurations of a Type-II BAW resonator.

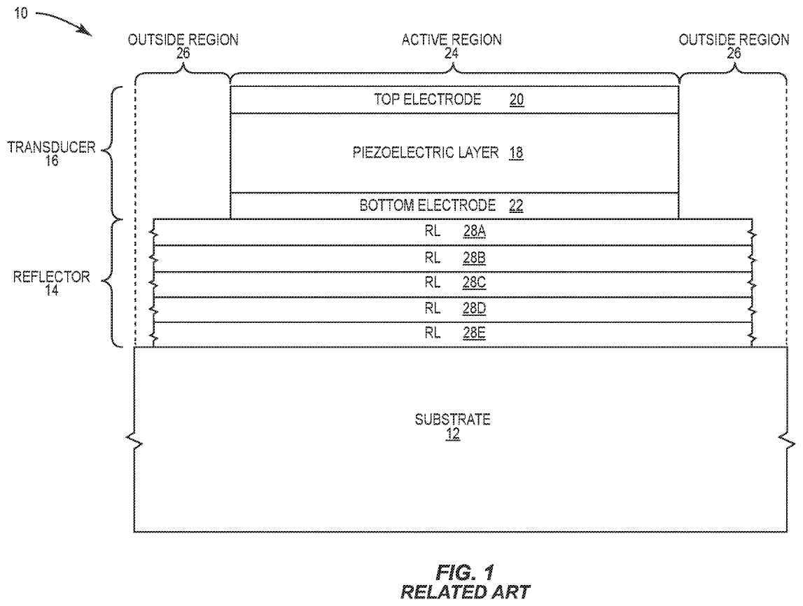

It will be understood that for clear illustrations, FIGS. 1-13B may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a bulk acoustic wave (BAW) resonator, and particularly to a BAW resonator with zero-coupling in border (BO) regions. The disclosed BAW resonator is provided with a high-quality factor, suppression of spurious modes, and suppression of BO modes.

Prior to delving into the details of these concepts, an overview of BAW resonators and filters that employ BAW resonators is provided. BAW resonators are used in many high-frequency filter applications. An exemplary BAW resonator 10 is illustrated in FIG. 1. The BAW resonator 10 is a solidly mounted resonator (SMR) type BAW resonator and generally includes a substrate 12, a reflector 14 mounted over the substrate 12, and a transducer 16 mounted over the reflector 14. The transducer 16 rests on the reflector 14 and includes a piezoelectric layer 18, which is sandwiched between a top electrode 20 and a bottom electrode 22. The top and bottom electrodes 20, 22 may be formed of tungsten (W), molybdenum (Mo), platinum (Pt), or like materials, and the piezoelectric layer 18 may be formed of aluminum nitride (AlN), zinc oxide (ZnO) or other appropriate piezoelectric materials. Although shown in FIG. 1 as including a single layer, the piezoelectric layer 18, the top electrode 20, and/or the bottom electrode 22 may include multiple layers of the same material, multiple layers in which at least two layers are different materials, or multiple layers in which each layer is a different material.

The BAW resonator 10 is divided into an active region 24 and an outside region 26. The active region 24 generally corresponds to the section of the BAW resonator 10 where the top and bottom electrodes 20, 22 overlap and also includes the layers below the overlapping top and bottom electrodes 20, 22. The outside region 26 corresponds to the section of the BAW resonator 10 that surrounds the active region 24.

For the BAW resonator 10, applying electrical signals across the top electrode 20 and the bottom electrode 22 excites acoustic waves in the piezoelectric layer 18. These acoustic waves primarily propagate vertically. A primary goal in the BAW resonator design is to confine these vertically-propagating acoustic waves in the transducer 16. Acoustic waves traveling upwardly are reflected back into the transducer 16 by an air-metal boundary at a top surface of the top electrode 20. Acoustic waves traveling downwardly are reflected back into the transducer 16 by the reflector 14, or by an air cavity, which is provided just below the transducer 16 in a film bulk acoustic resonator (FBAR).

The reflector 14 is typically formed by a stack of reflector layers (RL) 28A through 28E (referred to generally as reflector layers 28), which alternate in material composition to produce a significant reflection coefficient at the junction of adjacent reflector layers 28. Typically, the reflector layers 28 alternate between materials having high and low acoustic impedances, such as tungsten (W) and silicon dioxide (SiO₂). While only five reflector layers 28 are illustrated in FIG. 1, the number of reflector layers 28 and the structure of the reflector 14 will vary from one design to another.

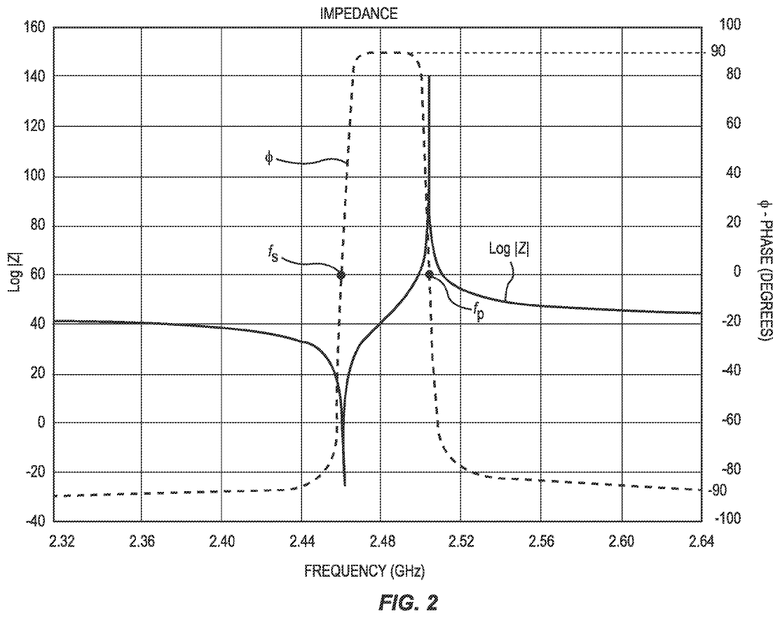

The magnitude (Z) and phase (φ) of the electrical impedance as a function of the frequency (GHz) for a relatively ideal BAW resonator 10 is provided in FIG. 2. The magnitude (Z) of the electrical impedance is illustrated by the solid line, while the phase (φ) of the electrical impedance is illustrated by the dashed line. A unique feature of the BAW resonator 10 is that it has both a resonance frequency and an antiresonance frequency. The resonance frequency is typically referred to as a series resonance frequency (ƒₛ), and the antiresonance frequency is typically referred to as a parallel resonance frequency (ƒₚ). The series resonance frequency (ƒₛ) occurs when the magnitude of the impedance, or reactance, of the BAW resonator 10 approaches zero. The parallel resonance frequency (ƒₚ) occurs when the magnitude of the impedance, or reactance, of the BAW resonator 10 peaks at a significantly high level. In general, the series resonance frequency (ƒₛ) is a function of the thickness or height of the piezoelectric layer 18 and the mass of the bottom and top electrodes 22, 20.

For the phase (φ), the BAW resonator 10 acts like an inductance that provides a 90° phase shift between the series resonance frequency (ƒₛ) and the parallel resonance frequency (ƒₚ). In contrast, the BAW resonator 10 acts like a capacitance that provides a −90° phase shift below the series resonance frequency (ƒₛ) and above the parallel resonance frequency (ƒₚ). The BAW resonator 10 presents a very low, near zero, resistance at the series resonance frequency (ƒₛ), and a very high resistance at the parallel resonance frequency (ƒₚ). The electrical nature of the BAW resonator 10 lends itself to the realization of a very high-quality factor (Q) inductance over a relatively short range of frequencies, which has proven to be very beneficial in high frequency filter networks, especially those operating at frequencies around 1.8 GHz and above.

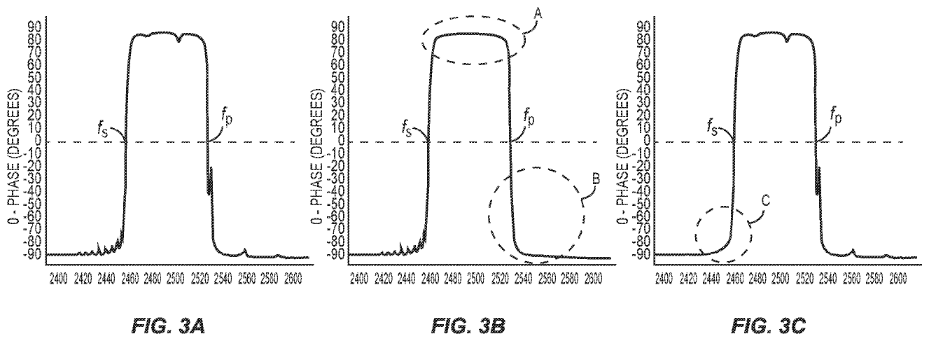

Unfortunately, the phase (φ) curve of FIG. 2 is representative of an ideal phase curve. In reality, approaching this ideal is challenging. A typical phase curve for the BAW resonator 10 of FIG. 1 is illustrated in FIG. 3A. Instead of being a smooth curve, the phase curve of FIG. 3A includes a ripple below the series resonance frequency (ƒₛ), between the series resonance frequency (ƒₛ) and the parallel resonance frequency (ƒₚ), and above the parallel resonance frequency (ƒₚ). The ripple is the result of spurious modes, which are caused by spurious resonances that occur in corresponding frequencies. While the vast majority of the acoustic waves in the BAW resonator 10 propagate vertically, various boundary conditions about the transducer 16 result in the propagation of lateral (horizontal) acoustic waves, which are referred to as lateral standing waves. The presence of these lateral standing waves reduces the potential quality factor (Q) associated with the BAW resonator 10.

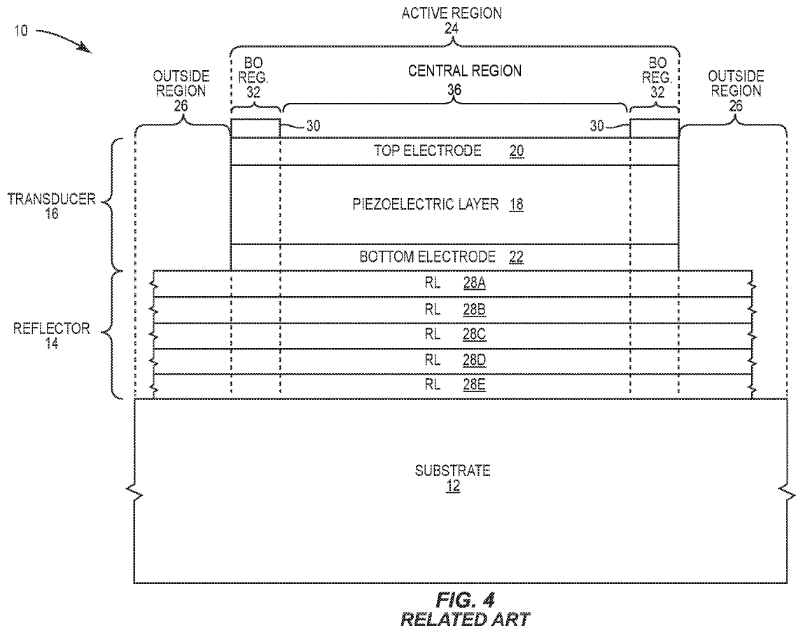

As illustrated in FIG. 4, a BO ring 30 is formed on or within (not shown) the top electrode 20 to suppress certain ones of the spurious modes. The spurious modes that are suppressed by the BO ring 30 are those above the series resonance frequency (ƒₛ), as highlighted by circles A and B in the phase curve of FIG. 3B. Circle A shows a suppression of the ripple, and thus the spurious mode, in the passband of the phase curve, which resides between the series resonance frequency (ƒₛ) and the parallel resonance frequency (ƒₚ). Circle B shows suppression of the ripple, and thus the spurious modes, above the parallel resonance frequency (ƒₚ). Notably, the spurious mode in the upper shoulder of the passband, which is just below the parallel resonance frequency (ƒₚ), and the spurious modes above the passband are suppressed, as evidenced by the smooth or substantially ripple free phase curve between the series resonance frequency (ƒₛ) and the parallel resonance frequency (ƒₚ) and above the parallel resonance frequency (ƒₚ).

The BO ring 30 corresponds to a mass loading of a portion of the top electrode 20 that extends about a periphery of the active region 24. In this regard, the BO ring 30 with mass loading forms a raised frame that is arranged about a periphery of the top electrode 20. The BO ring 30 may correspond to a thickened portion of the top electrode 20 or the application of additional layers of an appropriate material over the top electrode 20. The portion of the BAW resonator 10 that includes and resides below the BO ring 30 is referred to as a BO region 32. Accordingly, the BO region 32 corresponds to an outer, perimeter portion of the active region 24 and resides inside the active region 24. In addition, a central region 36 of the BAW resonator 10 is defined laterally inside of the BO region 32 and is not covered by the BO ring 30. While the BO ring 30 is effective at suppressing spurious modes above the series resonance frequency (ƒₛ), the BO ring 30 has little or no impact on those spurious modes below the series resonance frequency (ƒₛ), as shown in FIG. 3B. A technique referred to as apodization is often used to suppress the spurious modes that fall below the series resonance frequency (ƒₛ).

Apodization works to avoid, or at least significantly reduce, any lateral symmetry in the BAW resonator 10, or at least in the transducer 16 thereof. The lateral symmetry corresponds to the footprint of the transducer 16, and avoiding the lateral symmetry corresponds to avoiding symmetry associated with the sides of the footprint. For example, one may choose a footprint that corresponds to a pentagon instead of a square or rectangle. Avoiding symmetry helps reduce the presence of lateral standing waves in the transducer 16. Circle C of FIG. 3C illustrates the effect of apodization in which the spurious modes below the series resonance frequency (ƒₛ) are suppressed. Assuming that no BO ring 30 is provided, one can readily see in FIG. 3C that apodization fails to suppress those spurious modes above the series resonance frequency (ƒₛ). As such, the typical BAW resonator 10 employs both apodization and the BO ring 30.

A thickness or height of the BO ring 30 may be measured in a direction perpendicular to or away from a top surface of the piezoelectric layer 18 and a width of the BO ring 30 may be measured in a direction parallel to or laterally across the piezoelectric layer 18. The thickness and the width of the BO ring 30 may be concurrently tuned to provide suppression of spurious modes and to provide improvements to the quality factor at an antiresonance frequency (Qₚ). The added mass associated with the BO ring 30 typically causes the BO region 32 to resonate at a slightly lower frequency than other portions of the active region 24. As a result, the presence of BO rings can introduce undesirable modes, or BO modes, at frequencies below the series resonance frequency (ƒₛ).

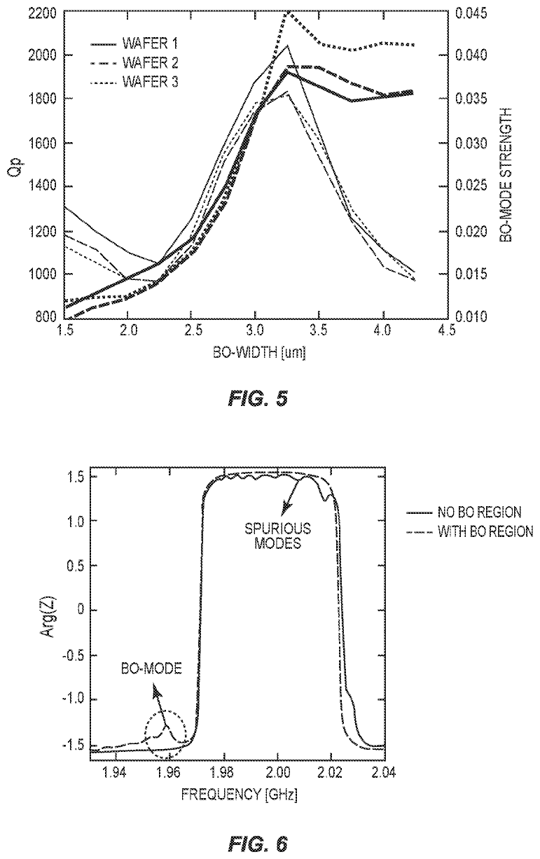

FIG. 5 is a diagram graphically illustrating the relationship of the BO ring width to the quality factor at the antiresonance frequency (Qₚ) and the relative strength of BO modes formed. In FIG. 5, the x-axis represents the BO ring width in microns (μm) while the primary y-axis represents the Qₚ and the secondary y-axis represents a relative strength or magnitude of the BO modes formed. The diagram of FIG. 5 plots data for three wafers that each include BAW resonators with varying BO ring widths. As shown, the Qₚ values generally increase with increasing BO ring widths and a highest Qₚ value corresponds to a BO ring width of just over 3 μm. As also shown, the BO mode strength also generally increases with increasing BO ring widths. For even higher BO ring widths, the Qₚ values decrease while the BO mode strength values remain high. In this manner, a BO ring that is tuned to provide a high Qₚ may also introduce undesirable BO modes to the corresponding BAW device.

FIG. 6 is a diagram graphically illustrating the phase curves for BAW resonators with and without BO rings. As illustrated, spurious modes that are present within the passband of a BAW resonator without a BO ring are suppressed with the addition of a BO ring; however, the presence of the BO ring introduces undesirable BO modes below the passband. BO modes may be introduced outside or even inside the passband of the filter and may restrict the design or use of BAW resonators for wide bandwidth filtering applications. If the BO modes are within the passband, insertion loss can be impacted. BO modes that are present outside of the passband can be problematic for BAW multiplexing applications where BAW filters of different frequency bands operate at the same time. In such multiplexing applications, BO modes of one BAW filter can fall into the passband of other BAW filters and introduce interference during multiplexing.

It is known that the main cause for the excitation of BO modes is a nonzero electromechanical coupling coefficient (k²e≠0) of a piezoelectric layer within a BO region (e.g., the piezoelectric layer 18 in the BO region 32). The electromechanical coupling coefficient of the piezoelectric layer is a function of a piezoelectric coefficient d of the piezoelectric layer, and the piezoelectric coefficient d is proportional to a polarization of the piezoelectric layer. Therefore, once the polarization of the piezoelectric layer varies, the piezoelectric coefficient d will change accordingly, and consequently, the electromechanical coupling coefficient of the BAW resonator will change as well. U.S. patent application Ser. No. 18/150,621 (U.S. Patent Provisional Application No. 63,324,961) and U.S. patent application Ser. No. 18/150,627 (U.S. Patent Provisional Application No. 63,324,968) describe methods to achieve a zero/reduced electromechanical coupling coefficient (k²e=0 or k²e-→0) in the BO region. However, the zero/reduced electromechanical coupling coefficient in the BO region may lead to increased lateral energy loss, resulting in a decrease in Qₚ values.

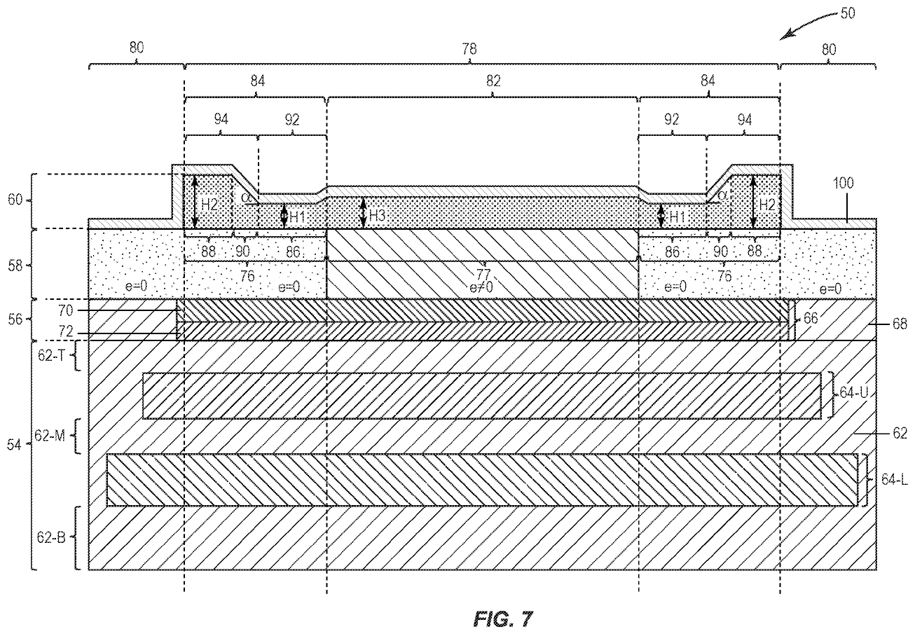

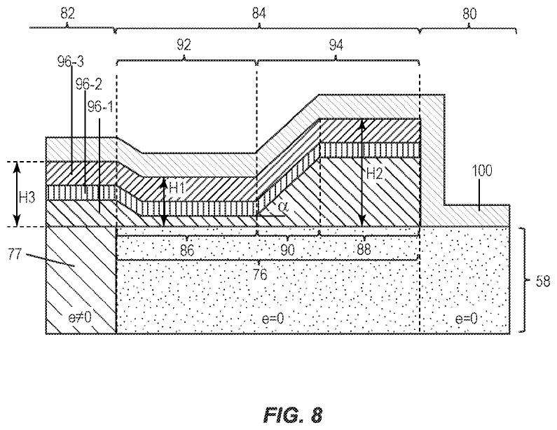

FIG. 7 is a cross-sectional diagram illustrating an exemplary BAW resonator 50 with zero-coupling in BO regions according to embodiments of the present disclosure. For the purpose of this illustration, the BAW resonator 50 is a BAW SMR and includes a reflector 54, a bottom electrode structure 56 over the reflector 54, a piezoelectric layer 58 over the bottom electrode structure 56, and a top electrode 60 over the piezoelectric layer 58. In different applications, the BAW resonator 50 may be a FBAR, in which the reflector 54 is omitted.

In detail, the reflector 54 includes a low acoustic impedance region 62, and multiple high acoustic impedance layers 64 are embedded within the low acoustic impedance region 62. Herein, there are two high acoustic impedance layers 64: an upper high acoustic impedance layer 64-U, and a lower high acoustic impedance section 64-L. In different applications, there may be fewer or more high acoustic impedance layers 64 embedded in the low acoustic impedance region 62. Herein, the lower high acoustic impedance layer 64-L resides over a bottom portion 62-B of the low acoustic impedance region 62. The upper high acoustic impedance layer 64-U is vertically above the lower high acoustic impedance layer 64-L and is separate from the lower high acoustic impedance layer 64-L by a middle portion 62-M of the low acoustic impedance region 62. A top portion 62-T of the low acoustic impedance region 62 is over the upper high acoustic impedance layer 64-U. The low acoustic impedance region 62 has lower acoustic impedance, lower density, and lower stiffness than the high acoustic impedance layers 64 and may be formed of SiO₂. Each high acoustic impedance layer 64 is formed of a high acoustic impedance material, such as W, Mo, or Pt. Each of the bottom portion 62-B of the low acoustic impedance region 62, the lower high acoustic impedance layer 64-L, the middle portion 62-M of the low acoustic impedance region 62, the upper high acoustic impedance layer 64-U, and the top portion 62-T of the low acoustic impedance region 62 is one RL of the reflector 54.

The bottom electrode structure 56 is formed over the top portion 62-T of the low acoustic impedance region 62 and includes a bottom electrode 66 and a planarization oxide 68. The bottom electrode 66 is vertically above the high acoustic impedance layers 64. The planarization oxide 68 surrounds the bottom electrode 66 and is capable of electrically separating the bottom electrode 66 with external bottom electrodes (not shown). The bottom electrode 66 may include at least two bottom electrode layers 70 and 72. The second bottom electrode layer 72 is over the top portion 62-T of the low acoustic impedance region 62 and may be formed of aluminum copper (AlCu), while the first bottom electrode layer 70 is over the second bottom electrode layer 72 and may be formed of W, Mo, or Pt. The planarization oxide 68 may be formed of SiO₂.

The piezoelectric layer 58 is formed over the bottom electrode structure 56 and at least fully covers the bottom electrode 66. The top electrode 60 is formed over the piezoelectric layer 58 and is vertically above the bottom electrode 66. The top electrode 60 includes a BO structure 76, which is positioned about a periphery of the top electrode 60, and a central electrode portion 77 surrounded by the BO structure 76.

The BAW resonator 50 is divided into an active region 78 and an outside region 80. The active region 78 corresponds to a section of the BAW resonator 50 where the top and bottom electrodes 60, 66 overlap and also includes the layers above, in-between, and below the overlapping top and bottom electrodes 60, 66. The outside region 80 corresponds to sections of the BAW resonator 50 that surround the active region 78. The active region 78 is further divided into a central region 82 and BO regions 84. The BO regions 84 correspond to sections of the BAW resonator 50 that include, reside over, and reside below the BO structure 76. The central region 82 is defined laterally within the BO regions 84 and does not overlap with the BO structure 76. The central electrode portion 77 of the top electrode 60 is confined in the central region 82

Notably, the bottom electrode 66 may extend beyond the peripheral edges of the top electrode 60. As previously described, the active region 78 is formed where the top and bottom electrodes 60, 66 overlap. In this manner, misalignment of the top electrode 60 with the bottom electrode 66 during fabrication may impair performance of the BAW resonator 50. By arranging the bottom electrode 66 with larger lateral dimensions than the top electrode 60, alignment tolerances for placement of the top electrode 60 may be increased, thereby improving manufacturing tolerances.

In this illustration, the BO structure 76 includes a first recessed frame 86 with a first height H1 (as measured from a top surface of the piezoelectric layer 58), a raised frame 88 with a second height H2 (as measured from the top surface of the piezoelectric layer 58), and a transition section 90 laterally between the first recessed frame 86 and the raised frame 88. The raised frame 88 may extend about the periphery of the top electrode 60, such that outer peripheral edges of the raised frame 88 may be peripheral edges of the top electrode 60. The first recessed frame 86 is connected to the raised frame 88 via the transition section 90 and is confined in the raised frame 88. In addition, the central electrode portion 77, which is confined in the central region 82 of the BAW resonator 50, has a third height H3 that is greater than the first height H1 of the first recessed frame 86. Typically, the third height H3 of the central electrode portion 77 is less than the second height H2 of the raised frame 88 (i.e., H2>H3>H1). In some applications, the third height H3 of the central electrode portion 77 may be greater than the second height H2 of the raised frame 88 (i.e., H3>H2>H1). A height of the transition section 90 varies from the first height H1 of the first recessed frame 86 to the second height H2 of the raised frame 88 to form a tapered wall. An angle a formed between the tapered wall of the transition section 90 and a horizontal plane (e.g., parallel with a top surface of the piezoelectric layer 58) is between 30 and 60 degrees. Height ratios among the first height H1 of the first recessed frame 86, the second height H2 of the raised frame 88, and the third height H3 of the central electrode portion 77 are dependent on materials used to form the first recessed frame 86 and the raised frame 88.

Herein, the BO regions 84 include a recessed BO region 92 and a mass loading BO region 94, each of which has a ring shape. The recessed BO region 92 corresponds to sections of the BAW resonator 50 that include, reside over, and reside below the first recessed frame 86. The mass loading BO region 94, on the other hand, corresponds to sections of the BAW resonator 50 that include, reside over, and reside below the raised frame 88 and the transition section 90. As such, the mass loading BO region 94 is laterally contiguous to the outside region 80 and extends about the periphery of the active region 78, the recessed BO region 92 is laterally contiguous to and surrounded by the mass loading BO region 94, and the central region 82 is laterally contiguous to and surrounded by the recessed BO region 92.

FIG. 8 illustrates details of the BO structure 76 of the top electrode 60. In this illustration, the top electrode 60 is composed of a first top electrode layer 96-1 formed directly over the piezoelectric layer 58, a second top electrode layer 96-2 formed over the first top electrode layer 96-1, and a third top electrode layer 96-3 formed over the second top electrode layer 96-2. The first top electrode layer 96-1 may be formed of W, Mo, Pt, or other electrically conductive materials with high acoustic impedance properties. The second electrode layer 96-2 may be formed of Titanium Tungsten (TiW) or Titanium (Ti) and function as a seed layer. The third top electrode layer 96-3 may be formed of AlCu or other highly electrically conductive materials. The first recessed frame 86 and the raised frame 88 are formed due to thickness variations of one or more top electrode layers 96.

For the purpose of this illustration, the first recessed frame 86 and the raised frame 88 are formed due to thickness variations of the first top electrode layer 96-1. In the first recessed frame 86, the first top electrode layer 96-1 has a thickness reduction (compared to a thickness of the first top electrode layer 96-1 within the central electrode portion 77), while the second and third top electrode layers 96-2 and 96-3 have no thickness change (compared to thicknesses of the second and third top electrode layers 96-2 and 96-3 within the central electrode portion 77, respectively). In the raised frame 88, the first top electrode layer 96-1 has a thickness increment (compared to the thickness of the first top electrode layer 96-1 within the first recessed frame 86), while the second and third top electrode layers 96-2 and 96-3 have no thickness change (compared to thicknesses of the second and third top electrode layers 96-2 and 96-3 within the central electrode portion 77, respectively). In different applications, the first recessed frame 86 and the raised frame 88 may be formed by thickness variations of the second top electrode layer 96-2, thickness variations of the third top electrode layer 96-3, or thickness variations of any combination of the first, second, and third top electrode layers 96-1, 96-2, and 96-3 (not shown).

For non-limited examples, the piezoelectric layer 58 may be formed of Scandium aluminum nitride (ScₓAl₁₋ₓN), Lead Zirconate Titanate (PZT), Lead titanate (PTO), Barium Titanate (BTO), Hafnium Oxide (HfO₂) or the like. Herein, a first portion of the piezoelectric layer 58, which is confined in the recessed BO region 92 and aligned underneath the first recessed frame 86, has a zero electromechanical coupling tensor (e=0). A second portion of the piezoelectric layer 58, which is confined in the mass loading BO region 94 and aligned underneath the raised frame 88 and the transition section 90, has a zero electromechanical coupling tensor (e=0). In other words, portions of piezoelectric layer 58, which are confined in the BO regions 84 and aligned underneath the BO structure 76 have a zero electromechanical coupling tensor (e=0). In addition, a third portion of the piezoelectric layer 58, which is confined in the outside region 80, has a zero electromechanical coupling tensor (e=0). Furthermore, a central portion of the piezoelectric layer 58, which is confined in the central region 82, aligned underneath the central electrode portion 77, and is not covered by the BO structure 76, has a non-zero electromechanical coupling tensor (e≠0) and is configured to provide the main resonance of the BAW resonator 50. In some applications, the first, second, and third portions of the piezoelectric layer 58 may have an extremely low electromechanical coupling tensor instead of a zero electromechanical coupling tensor, where the extremely low electromechanical coupling tensor is at most 10% of the non-zero electromechanical coupling tensor in the central portion of the piezoelectric layer 58.

Furthermore, the BAW resonator 50 may also include a passivation layer 100 to protect the exemplary BAW resonator 50 from an external environment. The passivation layer 100 covers the top electrode 60 and portions of the piezoelectric layer 58 exposed through the top electrode 60. The passivation layer 100 may be formed of Silicon Nitride (SIN), SiO₂, or Silicon Oxynitride (SiON).

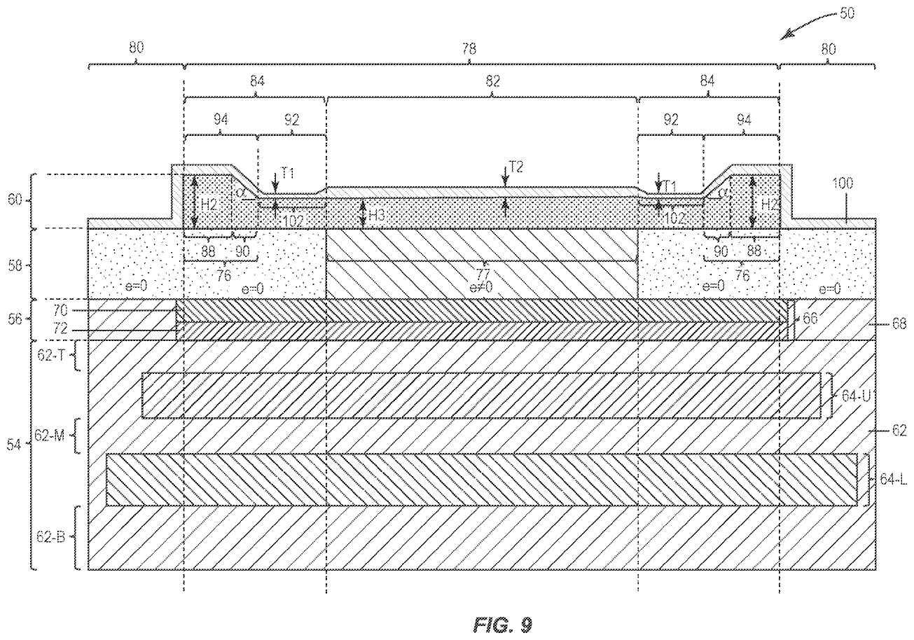

In one embodiment, the passivation layer 100 may have a uniform thickness between 250 Å and 5000 Å and does not add further recessed or mass loading to the top electrode 60. In another embodiment, the passivation layer 100 may also have thickness variations and contribute recessed and/or mass loading to the top electrode 60. As illustrated in FIG. 9, the passivation layer 100 includes a second recessed frame 102, while the BO structure 76 of the top electrode 60 does not include the first recessed frame 86 but only includes the transition section 90 and the raised frame 88. In this illustration, the mass loading BO region 94 still corresponds to the sections of the BAW resonator 50 that include, reside over, and reside below the raised frame 88 and the transition section 90. The recessed BO region 92, which is contiguous to and confined in the mass loading BO region 94, however, corresponds to sections of the BAW resonator 50 that include and reside below the second recessed frame 102. In other words, the second recessed frame 102 of the passivation layer 100 is laterally adjacent to and confined in the transition section 90 of the top electrode 60. The BO regions 84 of the BAW 50 still include both the recessed BO region 92 and the mass loading BO region 94, while the central region 82 is still surrounded by the BO regions 84.

Herein, a portion of the top electrode 60 confined in the recessed BO region 92 and the central electrode portion 77 confined in the central region 82 have the same third height H3. Accordingly, the height of the transition section 90 varies from the third height H3 to the second height H2 of the raised frame 88. In the recessed BO region 92, the passivation layer 100 (i.e., the second recessed frame 102) has a first thickness T1, while in the central region 82, the passivation layer 100 has a second thickness T2. The first thickness T1 may be 70%-90% of the second thickness T2. In addition, the passivation layer 100 in the mass loading BO region 94 and in the outside region 80 may have a thickness the same as the first thickness T1 or the same as the second thickness T2.

The first portion of the piezoelectric layer 58, which is confined in the recessed BO region 92 and aligned underneath the second recessed frame 102, has a zero electromechanical coupling tensor (e=0). The second portion of the piezoelectric layer 58, which is confined in the mass loading BO region 94 and aligned underneath the BO structure 76, has a zero electromechanical coupling tensor (e=0). As such, portions of piezoelectric layer 58, which are confined in the BO regions 84 have a zero electromechanical coupling tensor (e=0). The third portion of the piezoelectric layer 58, which is confined in the outside region 80, still has a zero electromechanical coupling tensor (e=0). The central portion of the piezoelectric layer 58, which is confined in the central region 82 and is not covered by the second recessed frame 102 and the BO structure 76, has a non-zero electromechanical coupling tensor (e≠0), and is configured to provide the main resonance of the BAW resonator 50. In some applications, the first, second and third portions of the piezoelectric layer 58 may have an extremely low electromechanical coupling tensor instead of a zero electromechanical coupling tensor, where the extremely low electromechanical coupling tensor is at most 10% of the non-zero electromechanical coupling tensor of the central portion of the piezoelectric layer 58.

Notice that, regardless that the recessed BO region 92 is determined by the second recessed frame 102 of the passivation layer 100 (as shown in FIG. 9) or determined by the first recessed frame 86 of the top electrode 60 (as shown in FIGS. 7-8), a height of the recessed BO region 92 is always less than a height of the central region 82 and a height of the mass loading BO region 94 is always greater than the height of the recessed BO region 92. Typically, the height of the mass loading BO region 94 is greater than the height of the central region 82 (as shown in FIGS. 7-9). In some applications, the height of the mass loading BO region 94 may be less than the height of the central region 82.

In addition, the BAW resonator 50, which includes one first/second recessed frame 86/102, the raised frame 88, and zero/reduced coupling portions of the piezoelectric layer 58, can be either a Type-I resonator or a Type-II resonator. Herein, a frame combination of the first/second recessed frames 86/102 and the raised frame 88 lead to an improved quality factor for the BAW resonator 50, compared to those of a resonator with only a recessed frame or a raised frame. On the other hand, due to the zero/reduced electromechanical coupling tensor in the first and second portions of the piezoelectric layer 58 (confined in the BO regions 84), there will be neglectable BO modes in the BAW resonator 50. The zero/reduced electromechanical coupling tensor in the first and second portions of the piezoelectric layer 58 may also help confine the energy inside the BAW resonator 50 and reduce lateral loss.

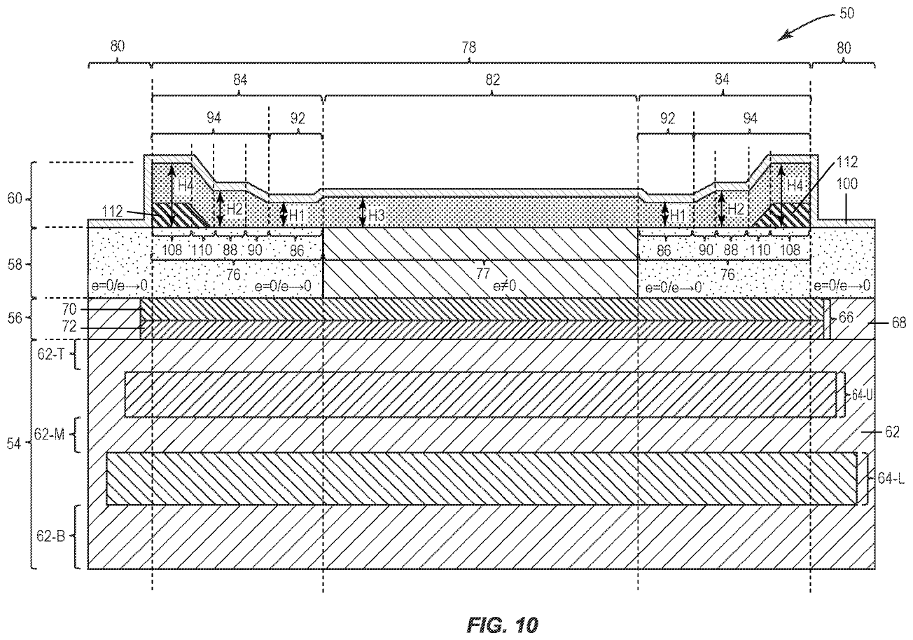

As shown in FIGS. 7-9, within the mass loading BO region 94, the BO structure 76 only includes one transition section 90 and one raised frame 88 forming a single-step configuration. In different applications, within the mass loading BO region 94, the BO structure 76 may include two transition sections and two raised frames forming a dual-step configuration as illustrated in FIG. 10. Within the mass loading BO region 94, besides the raised frame 88 and the transition section 90, the BO structure 76 further includes a second raised frame 108 with a fourth height H4 and a second transition section 110. Herein, the raised frame 88 is an inner raised frame connected with the first recessed frame 86 via the transition section 90. In different applications, the first recessed frame 86 of the top electrode 60 may be replaced by the second recessed frame 102 of the passivation layer 100 (not shown). The second raised frame 108 is an outer raised frame, which may extend about the periphery of the top electrode 60 (e.g., outer peripheral edges of the second raised frame 108 may be the peripheral edges of the top electrode 60) and is connected to the inner raised frame 88 via the second transition section 110. A height of the second transition section 110 varies from the second height H2 of the inner raised frame 88 to the fourth height H4 of the outer raised frame 108.

As described above, the inner raised frame 88 is formed due to a thickness increment of one or more top electrode layers 96 (e. g, the thickness increment of the first top electrode layer 96-1 as illustrated in FIG. 8). In this illustration, the outer raised frame 108 is formed due to a combination of the thickness increment of one or more top electrode layers 96 and a dielectric BO ring 112 (with a thickness H4-H2) about the outer periphery of the top electrode 60. The dielectric BO ring 112 is located vertically between the top electrode layers 96 and the piezoelectric layer 58. The dielectric BO ring 112 may be formed of SiO₂. Herein, the portions of the piezoelectric layer 58, which are confined in the BO regions 84 and aligned underneath the BO structure 76 (e.g., underneath the first recessed frame 86, the transition section 90, the raised frame 88, the second transition section 110, and the second raised frame 108) has a zero/extremely low electromechanical coupling tensor (e=0 or e→0).

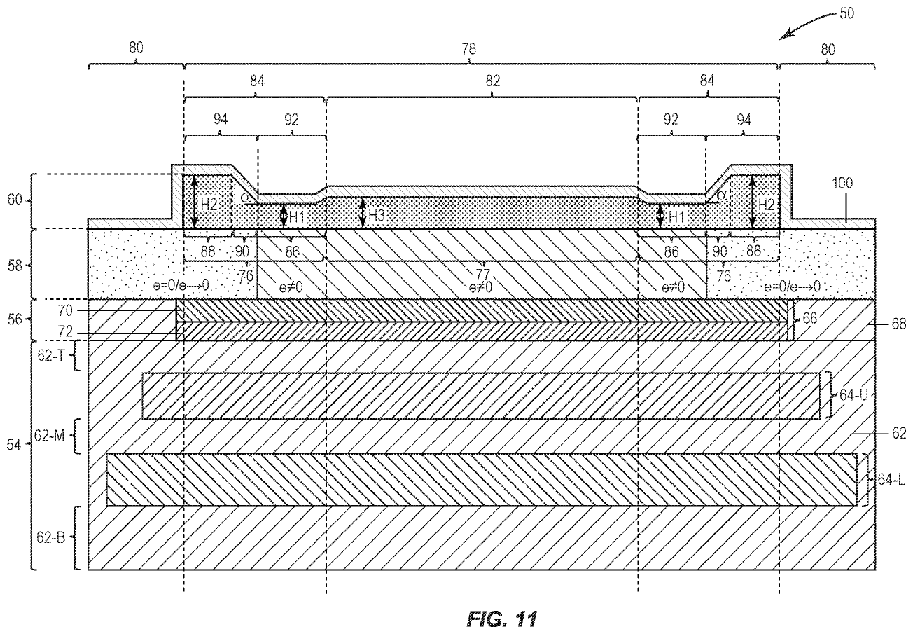

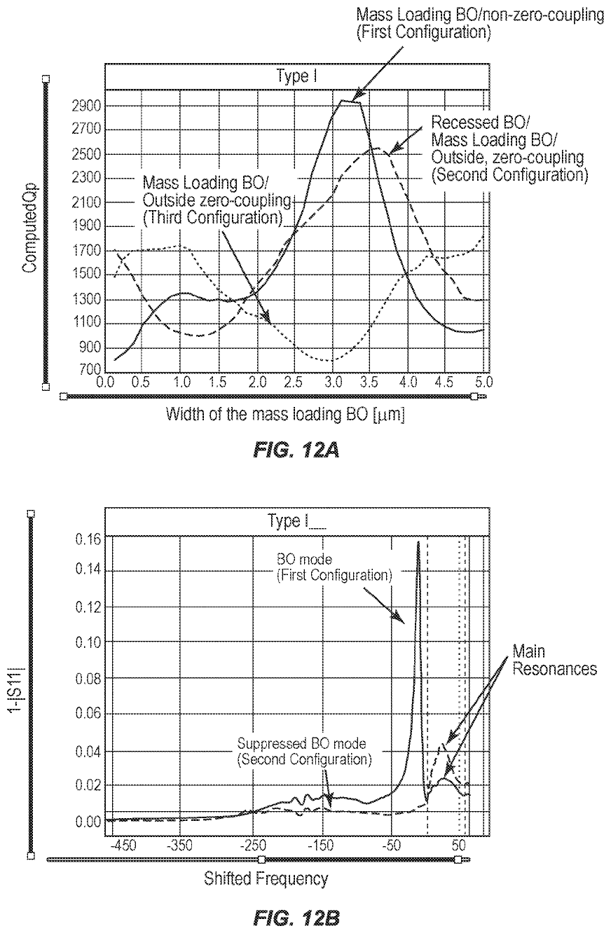

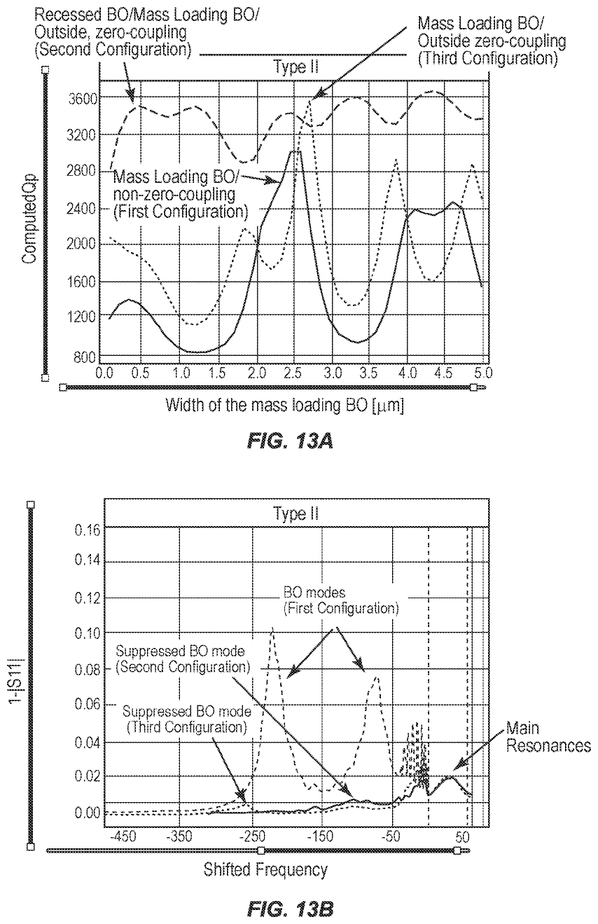

To achieve a desired high quality factor and effectively suppress the BO modes, the BAW resonator 50 (either a Type-I resonator or a Type-II resonator) could have both the recessed and raised frames and zero/reduced-coupling in the first, second, and third portions of the piezoelectric layer 58 (i.e., portions of the piezoelectric layer 58 confined in the recessed BO region 92, the mass loading BO region 94, and the outside region 80, respectively) (see FIGS. 7-10). For the Type-I BAW resonators, when the BAW resonator does not include the recessed frame but only the raised frame(s), and/or the piezoelectric layer has fewer portions with zero/reduced electromechanical coupling tensor (e.g., zero/reduced-coupling only in the second and third portions of the piezoelectric layer 58, which are confined in the mass loading BO region 94 and the outside region 80, not shown), the quality factor of the BAW resonator will significantly decrease (details shown in FIGS. 12A-12B), which is due to reduced lateral energy confinement. However, for Type-II BAW resonators, when the BAW resonator does not include the recessed frame but only the raised frame(s), and/or the piezoelectric layer has fewer portions with a zero/reduced electromechanical coupling tensor (e.g., zero/reduced-coupling only in the second and third portions of the piezoelectric layer 58, which are confined in the mass loading BO region 94 and the outside region 80, as illustrated in FIG. 11), the quality factor of the BAW resonator may still achieve a relative high value (details shown in FIGS. 13A-13B).

In FIG. 11, the first portion of the piezoelectric layer 58, which is confined in the recessed BO region 92 and aligned underneath the first recessed frame 86 (or aligned underneath the second recessed frame 102, not shown), and the central portion of the piezoelectric layer 58, which is confined in the central region 82, have a non-zero electromechanical coupling tensor (e≠0). The second portion of the piezoelectric layer 58, which is confined in the mass loading BO region 94 and aligned underneath the raised frame 88 and the transition section 90, and the third portion of the piezoelectric layer 58, which is confined in the outside region 80, have a zero/reduced electromechanical coupling tensor (e=0 or e→0). In some applications, the third portion of the piezoelectric layer 58, which is confined in the outside region 80, may have a non-zero electromechanical coupling tensor as the central portion of the piezoelectric layer 58 (not shown). Notice that the value of the electromechanical coupling tensor in the outside region 80 (zero or non-zero) has a negligible effect on a quality factor/BO mode suppression of the BAW resonator 50.

FIGS. 12A-12B illustrate simulation results for various configurations of a Type-I BAW resonator. FIG. 12A shows quality factor simulation results for the Type-I BAW resonator with three different configurations: 1) the first configuration of the Type-I BAW resonator is the same as that shown in FIGS. 4, 2) the second configuration of the Type-I BAW resonator is the same as that shown in FIG. 9, and 3) the third configuration of the Type-I BAW resonator includes a mass loading BO region (e.g., the mass loading BO region 94) but does not include an recessed BO region (e.g., the recessed BO region 92), where portions of the piezoelectric layer confined in the mass loading BO region and the outside region (e.g., the mass loading BO region 94 and the outside region 80) are zero-coupling (not shown). FIG. 12B shows 1−|S₁₁| response simulation results for the Type-I BAW resonator with the first and the second configurations (1−|S₁₁| is equal to the power ratio lost in a resonator).

It is clearly shown that for the Type-I resonator with either the first configuration or the second configuration, its quality factor can achieve a relatively high value by selecting an optimized width of the mass loading BO region. In this illustration, the Type-I resonator with the first configuration can reach 2900 Qp when the mass loading BO region has a 3.25 μm width, while the Type-I resonator with the second configuration can reach 2500 Qp when the mass loading BO region has a 3.6 μm width. However, the Type-I resonator with the third configuration can only reach a maximum 1800 Qp, which is due to the reduced lateral energy confinement. On the other hand, the Type-I resonator with the first configuration has very strong undesired BO modes, while the Type-I resonator with the second configuration has superiorly suppressed BO modes. Accordingly, the Type-I resonator with the second configuration (as shown in FIG. 9) has a relative high-quality factor with superiorly suppressed BO modes.

Notice that a conventional Type-I resonator typically does not need a recessed frame since it does not have spurious modes below the series resonance frequency (fs). However, the proposed configurations (as shown in FIGS. 7-10) for the Type-I resonator include a recessed frame (e.g., the first recessed frame 86 or the second recessed frame 102) and the zero-coupling piezoelectric layer portion underneath to achieve the superior quality factor outcome.

FIGS. 13A-13B illustrate simulation results for various configurations of a Type-II BAW resonator. FIG. 13A shows quality factor simulation results for the Type-II BAW resonator with three different configurations: 1) the first configuration of the Type-II BAW resonator is the same as that shown in FIGS. 4, 2) the second configuration of the Type-II BAW resonator is the same as that shown in FIG. 9, and 3) the third configuration of the Type-II BAW resonator includes a mass loading BO region (e.g., the mass loading BO region 94) but does not include a recessed BO region (e.g., the recessed BO region 92), where portions of the piezoelectric layer confined in the mass loading BO region and the outside region (e.g., the mass loading BO region 94 and the outside region 80) are zero-coupling (not shown). FIG. 13B shows 1−|S₁₁| response simulation results for the Type-II BAW resonator with the first, second, and third configurations.

It is clearly shown that the Type-Il resonator with the second configuration has the maximum quality factor and the highest average quality factor over a width range of the mass loading BO region. In this illustration, the Type-II resonator with the second configuration can reach 3700 Qp when the mass loading BO region has a 4.3 μm width and can achieve an average 3450 Qp over the width range 0.2 μm-5 μm. For the Type-II resonator with either the first configuration or the third configuration, its quality factor can achieve a relatively high value by selecting an optimized width of the mass loading BO region. In this illustration, the Type-II resonator with the first configuration can reach 3000 Qp when the mass loading BO region has a 2.5 μm width, while the Type-II resonator with the third configuration can reach 3600 Qp when the mass loading BO region has a 2.7 μm width. On the other hand, the Type-II resonator with the first configuration has strong undesired BO modes, while the Type-II resonator with the second or third configuration has superiorly suppressed BO modes (the Type-II resonator with the second configuration has the minimum BO modes).

Notice that to achieve comparable desired Qp values and BO suppression results, the third configuration requires a much larger width (e.g., 2.7 μm for 3600 Qp) than the second configuration (e.g., 0.5 μm for 3500 Qp). As such, the second configuration (with a zero electromechanical coupling tensor in the recess BO+mass loading BO+outside regions) may have a smaller total zero-coupling width than the third configuration (with a zero electromechanical coupling tensor in the mass loading BO+outside regions), which will lead to less of a drop of coupling k²e of the whole resonator. Accordingly, the Type-II resonator with the second configuration (as shown in FIG. 9) can achieve desired outcomes in quality factors and BO mode suppression without significantly sacrificing the coupling of the whole resonator.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A Bulk Acoustic Wave (BAW) resonator, comprising:
a bottom electrode;
a top electrode; and
a piezoelectric layer sandwiched between the bottom electrode and the top electrode, wherein:
the piezoelectric layer is formed of a material, which has a box-shape polarization-electric field (P-E) curve;
the BAW resonator is divided into an active region and an outside region, wherein the active region corresponds to a section of the BAW resonator where the top electrode and the bottom electrode overlap, while the outside region corresponds to sections of the BAW resonator surrounding the active region;
the active region is divided into a central region, a recessed border (BO) region, and a mass loading BO region, wherein the mass loading BO region is laterally contiguous to the outside region and about a periphery of the active region, the recessed BO region is laterally contiguous to and surrounded by the mass loading BO region, and the central region is laterally contiguous to and surrounded by the recessed BO region, such that the recessed BO region is in direct contact with the mass loading BO region and the central region;
a height of the recessed BO region is less than a height of the central region and a height of the mass loading BO region is greater than the height of the recessed BO region; and
a first portion of the piezoelectric layer, which is confined in the mass loading BO region, has a zero electromechanical coupling tensor, while a central portion of the piezoelectric layer, which is confined in the central region, has a non-zero electromechanical coupling tensor.

2. The BAW resonator of claim 1, wherein a second portion of the piezoelectric layer, which is confined in the recessed BO region, has a zero electromechanical coupling tensor.

3. The BAW resonator of claim 2, wherein a third portion of the piezoelectric layer, which is confined in the outside region, has a zero electromechanical coupling tensor.

4. The BAW resonator of claim 1, wherein the piezoelectric layer is formed of one of a group consisting of Scandium aluminum nitride, Lead Zirconate Titanate, Lead titanate, Barium Titanate, and Hafnium Oxide.

5. The BAW resonator of claim 1, wherein the height of the mass loading BO region is greater than the height of the central region.

6. The BAW resonator of claim 1, wherein the height of the central region is greater than the height of the mass loading BO region.

7. The BAW resonator of claim 3, wherein the BAW resonator is a Type-I resonator or a Type-II resonator.

8. The BAW resonator of claim 1, wherein:
a second portion of the piezoelectric layer, which is confined in the recessed BO region, has a non-zero electromechanical coupling tensor; and
the BAW resonator is a Type-II resonator.

9. The BAW resonator of claim 8, wherein a third portion of the piezoelectric layer, which is confined in the outside region, has a zero electromechanical coupling tensor.

10. The BAW resonator of claim 1, wherein the top electrode includes a BO structure about a periphery of the top electrode, wherein:
the BO structure includes a recessed frame with a first height, a raised frame with a second height, and a transition section laterally between the recessed frame and the raised frame, wherein the second height is greater than the first height, and a height of the transition section varies from the first height of the recessed frame to the second height of the raised frame to form a tapered wall;
the raised frame is about the periphery of the top electrode, such that outer peripheral edges of the raised frame are peripheral edges of the top electrode, and the recessed frame is connected to the raised frame via the transition section and surrounded by the raised frame;
a central electrode portion of the top electrode, which is confined in the central region of the BAW resonator, has a third height that is greater than the first height of the recessed frame; and
the recessed BO region corresponds to sections of the BAW resonator that include, reside over, and reside below the recessed frame, and the mass loading BO region corresponds to sections of the BAW resonator that include, reside over, and reside below the raised frame and the transition section, wherein a height variation among the central region, the recessed BO region, and the mass loading BO region is formed due to a height variation of the top electrode.

11. The BAW resonator of claim 10, wherein:
the top electrode is composed of a first top electrode layer formed directly over the piezoelectric layer, a second top electrode layer formed over the first top electrode layer, and a third top electrode layer formed over the second top electrode layer; and
the recessed frame, the transition section, and the raised frame of the top electrode are formed due to thickness variations of one or more of the first top electrode layer, the second top electrode layer, and the third top electrode layer.

12. The BAW resonator of claim 11, wherein the recessed frame, the transition section, and the raised frame of the top electrode are formed due to a thickness variation of the first top electrode layer.

13. The BAW resonator of claim 11, wherein:
the first top electrode layer is formed of one of a group consisting of tungsten (W), molybdenum (Mo), platinum (Pt);
the second electrode layer is formed of Titanium Tungsten (TiW) or Titanium (Ti); and
the third top electrode layer is formed of aluminum copper (AlCu).

14. The BAW resonator of claim 11 further comprising a passivation layer that covers the top electrode and portions of the piezoelectric layer exposed through the top electrode, wherein the passivation layer has a uniform thickness.

15. The BAW resonator of claim 1, wherein the top electrode includes a BO structure about a periphery of the top electrode, wherein:
the BO structure includes a recessed frame with a first height, an inner raised frame with a second height, a first transition section laterally between the recessed frame and the inner raised frame, an outer raised frame with a third height, and a second transition section laterally between the inner raised frame and the outer raised frame, wherein the second height is greater than the first height and less than the third height, a height of the first transition section varies from the first height of the recessed frame to the second height of the inner raised frame, while a height of the second transition section varies from the second height of the inner raised frame to the third height of the outer raised frame;
the outer raised frame is about the periphery of the top electrode, such that outer peripheral edges of the outer raised frame are peripheral edges of the top electrode;
the inner raised frame is connected to the outer raised frame via the second transition section and surrounded by the outer raised frame;
the recessed frame is connected to the inner raised frame via the first transition section and surrounded by the inner raised frame;
a central electrode portion of the top electrode, which is confined in the central region of the BAW resonator, has a fourth height that is greater than the first height of the recessed frame; and
the recessed BO region corresponds to sections of the BAW resonator that include, reside over, and reside below the recessed frame, and the mass loading BO region corresponds to sections of the BAW resonator that include, reside over, and reside below a combination of the first transition section, the inner raised frame, the second transition section, and the outer raised frame.

16. The BAW resonator of claim 15 further includes a dielectric BO ring about the periphery of the active region, wherein:
the top electrode is composed of multiple top electrode layers that are formed directly over the piezoelectric layer and extend over the dielectric BO ring; and
a height variation among the central region, the recessed BO region, and the mass loading BO region is formed due to a combination of a thickness variation of the top electrode layers of the top electrode and a thickness of the dielectric BO ring.

17. The BAW resonator of claim 1 further comprising a passivation layer that covers the top electrode and portions of the piezoelectric layer exposed through the top electrode, wherein the passivation layer is formed of Silicon Nitride (SiN), silicon dioxide (SiO₂), or Silicon Oxynitride (SiON).

18. The BAW resonator of claim 17, wherein:
the top electrode includes a BO structure with a raised frame and a transition section, and the passivation layer includes a recessed frame;
the raised frame is about a periphery of the top electrode, such that outer peripheral edges of the raised frame are peripheral edges of the top electrode, and the transition section is laterally contiguous to and surrounded by the raised frame;
the recessed frame of the passivation layer is laterally adjacent to and confined in the transition section of the top electrode;
a thickness of the recessed frame is less than a thickness of the passivation layer within the central region; and
the recessed BO region corresponds to sections of the BAW resonator that include and reside below the recessed frame of the passivation layer, and the mass loading BO region corresponds to sections of the BAW resonator that include, reside over, and reside below the raised frame and the transition section.

19. The BAW resonator of claim 18, wherein:
the top electrode is composed of multiple top electrode layers that are formed directly over the piezoelectric layer; and
a height variation among the central region, the recessed BO region, and the mass loading BO region is formed due to the recessed frame of the passivation layer and the BO structure of the top electrode.

20. The BAW resonator of claim 19, wherein:
portions of the top electrode confined within the central region and the recessed BO region have a uniform thickness, and a height variation between the central region and the recessed BO region is due to a thickness variation of the passivation layer; and
a height variation between the recessed BO region and the mass loading BO region is due to a thickness variation of the top electrode layers.
